(19) United States
(12) Patent Application Publication
(10) Pub. No.: US 2006/0026492 A1
(43) Pub. Date: Feb. 2, 2006

(54) Method and apparatus for managing a deinterleaving buffer in a mobile communication system using block interleaving

(75) Inventors: Jong-Hun Rhee, Suwon-si (KR); Yong-Chan Kim, Seoul (KR); Su-Yean Kim, Incheon (KR); Min-Goo KIM, Yongin-si (KR)

Correspondence Address: ROYLANCE, ABRAMS, BERDO & GOODMAN, L.L.P., 1300 19TH STREET, N.W., SUITE 600, WASHINGTON,, DC, 20036, US

(73) Assignee: Samsung Electronics Co., Ltd.

(21) Appl. No.: 11/192,184

(22) Filed: Jul. 29, 2005

(30) Foreign Application Priority Data
Jul. 29, 2004 (KR) 10-2004-0059961

(51) Int. Cl. H03M 13/00

(52) U.S. Cl. 714/784

(57) ABSTRACT

A method and apparatus are provided for managing a buffer that can reduce a buffer size and a number of buffers required for a receiving stage of a mobile communication system using block interleaving. In a deinterleaving buffer configured as a plurality of sub-buffers in a receiving stage of a mobile communication system for performing Reed-Solomon (RS) decoding on frames received through a wireless network, input buffer addresses of the received frames to be input to the deinterleaving buffer, and output buffer addresses of RS-decoded frames to be output to a higher layer, are set to be cyclic by a management process. The frames input to the deinterleaving buffer are RS-decoded in a sub-buffer unit and the RS-decoded frames are output to the higher layer. Newly received frames are stored in input addresses having a same pattern with a last pattern of the output addresses in the deinterleaving buffer.

### CROSS-REFERENCE TO RELATED APPLICATIONS

This application claims the benefit under 35 U.S.C. §119(a) of Korean Patent Application No. 10-2004-0059961 entitled “Method And Apparatus For Managing A Deinterleaving Buffer In A Mobile Communication System Using Block Interleaving” filed in the Korean Intellectual Property Office on Jul. 29, 2004, the entire disclosure of which is incorporated herein by reference.

### BACKGROUND OF THE INVENTION

1. Field of the Invention

The present invention relates generally to a method and apparatus for managing a buffer in a receiving stage of a mobile communication system using block interleaving. More particularly, the present invention relates to a buffer management method and apparatus that can reduce a buffer size and the number of buffers required for a receiving stage.

2. Description of the Related Art

With the development of communication technology, mobile communication systems have developed from voice service systems into both voice and data service systems. These mobile communication systems can provide broadcasting services as well as various data services. The Third Generation Partnership Project 2 (3GPP2) using code division multiple access (CDMA) proposes various systems for providing broadcasting services through various standardization tasks. According to CDMA2000 1x Revision D of various standards proposed for broadcasting services in 3GPP2, a broadcasting service is called broadcast and multicast service (BCMCS). In addition to CDMA2000 1x Revision D, standards for providing broadcasting services are also being created in High Rate Packet Data (HRPD) Revision A for a synchronous CDMA system. Hereinafter, the CDMA-based BCMCS service associated with the CDMA2000 1x Revision D and HRPD Revision A is referred to as the broadcasting service.

The broadcasting service is configured to transmit broadcasting data, for example, in a frame unit with a period of 20 ms. This broadcasting service can use an inner code such as a convolution code or turbo code for channel coding, and an outer code such as a Reed-Solomon (RS) code serving as a well-known error correction code.

To avoid a transmission error of successively generated broadcasting data, an RS code is used. This RS code is defined in the CDMA2000 1x Revision D specification. According to the CDMA2000 1x Revision D specification, for example, RS coding is performed using four sub-buffers for the broadcasting service. In the example, the RS coding can select one of the code rates 11/16, 12/16, 13/16, and 14/16. After an RS coding process and an inner coding process, broadcasting data is block-interleaved and the block-interleaved data is transmitted through a wireless network in a frame unit.

A conventional coding process for RS codes will now be described in greater detail with reference to FIG. 1. FIG. 1 is a block diagram illustrating an internal structure of a transmitting stage including outer coders 120 and an inner coder 140. In an example in which it is assumed that the outer coders 120 are RS coders, a conventional outer coding process and a conventional inner coding process can be described as follows with reference to FIG. 1.

In FIG. 1, transmission data bits are input to a demultiplexer (DEMUX) 110 for a predetermined time according to a predetermined code rate. The demultiplexer 110 then demultiplexes the input transmission data bits and outputs the demultiplexed transmission data bits to the outer coders 120. The outer coders 120 encode the transmission data bits stored in a plurality of sub-buffers (not illustrated) into RS codes. A multiplexer (MUX) 130 multiplexes the RS coded symbols stored in the sub-buffers, and outputs a result of the multiplexing to the inner coder 140, such as a channel coder.

Assuming that the number of frames of one code word is denoted by n and the number of systematic frames containing broadcasting data among the n frames is k, the n and k values are defined by (n,k)∈{(16,11),(16,12),(16,13),(16,14)}.

FIG. 2 illustrates an example of sub-buffers 21, 23, 25, and 27 used for RS coding. Part (A) of FIG. 2 illustrates an information order of transmission data before the RS coding, and part (B) illustrates an information order of transmission data after the RS coding. Part (C) of FIG. 2 illustrates a transmission order of data to be transmitted through a channel after the RS coding. In FIG. 2, each of the sub-buffers 21, 23, 25, and 27 stores, for example, 16 frames. Each frame is channel-coded through the inner coder 140.

The input transmission data bits of k systematic frames as indicated by “Info” in FIG. 2 are stored sequentially from the top of the sub-buffers 21, 23, 25, and 27, and n-k lower frames are stored as parity frames generated from the RS coding. When the n-k lower frames are generated from the k systematic frames through the RS coding as illustrated in part (B) of FIG. 2, a total of 64-frame data is provided. The 64 frames are then transmitted in order of first frames, second frames, and so on, from the sub-buffers 21, 23, 25, and 27 as illustrated in part (C) of FIG. 2. The numbers illustrated in part (C) of FIG. 2 are transmission sequence numbers of the frames. This method is the same as a conventional transmission method based on block interleaving.

A receiving stage of a mobile terminal using a broadcasting service requires a reception buffer in which block interleaving is performed. This buffer has the same size as a buffer used in a transmission stage, and uses a size of 64 frames. When the time required for decoding received RS-coded frames is considered, an output buffer with the same size as the reception buffer is additionally required. A method for managing a buffer in the reception stage will now be briefly described.

First, after the reception stage of the mobile terminal receives all 64 frames and performs inner decoding, the decoded frames are stored, for example, in four sub-buffers. Subsequently, the receiving stage performs an RS decoding process for the four sub-buffers and corrects an error of data. A higher layer of the receiving stage sequentially reads the RS-decoded frames from the sub-buffers, and sequentially stores newly received frames in an empty sub-buffer. This operation is repeated whenever 64-frame data is completely received.

According to the conventional buffer management method, the receiving stage requires a deinterleaving buffer with the same size as an interleaving buffer provided in the transmitting stage. Moreover, because the receiving stage must store RS-decoded frames in a separate buffer, it additionally requires an output buffer with the same size as the deinterleaving buffer.

When the conventional deinterleaving operation is applied in the receiving stage, the receiving stage requires twice the size of 64 frames of a buffer provided in the transmitting stage, i.e., a buffer size of 128 frames, and therefore memory resources may be inefficiently used. There is also a problem in that the efficiency of the receiving stage is degraded because a data copy operation is required for the receiving stage such that an output buffer can temporarily store decoded frames from the deinterleaving buffer after the RS decoding is performed.

Accordingly, a need exists for a system and method that can reduce a buffer size and the number of buffers required for a receiving stage of a mobile terminal using a broadcasting service.

### SUMMARY OF THE INVENTION

It is, therefore, an aspect of the present invention to substantially solve the above and other problems, and provide a method and apparatus for managing a deinterleaving buffer in a mobile communication system using block interleaving that can reduce a buffer size and the number of buffers required for a receiving stage of a mobile terminal using a broadcasting service.

It is another aspect of the present invention to provide a method and apparatus for managing a deinterleaving buffer in a mobile communication system using block interleaving that can improve the efficiency of a receiving stage of a mobile terminal using a broadcasting service.

The above and other aspects of the present invention can be achieved by providing a method for managing a deinterleaving buffer configured as a plurality of sub-buffers in a receiving stage of a mobile communication system for performing Reed-Solomon (RS) decoding on frames received through a wireless network. The method comprises the steps of setting cyclic patterns for input and output addresses of the deinterleaving buffer, performing the RS decoding in a sub-buffer unit after storing received frames in preset input addresses, outputting RS-decoded frames to a higher layer at a preset time point, and storing newly received frames in the input addresses having a same pattern with a last pattern of the output addresses in the deinterleaving buffer.

The above and other aspects of the present invention can also be achieved by providing an apparatus for managing a buffer configured as a plurality of sub-buffers in a receiving stage of a mobile communication system for performing Reed-Solomon (RS) decoding on frames received through a wireless network. The apparatus comprises an outer decoder for performing the RS decoding on frames input to a deinterleaving buffer, the deinterleaving buffer comprising a plurality of sub-buffers for inputting and outputting the frames received according to preset input and output addresses, and a controller for setting input and output indices of the received frames and cyclic input and output addresses of the deinterleaving buffer, and for controlling the outer decoder and the deinterleaving buffer to output an RS-decoded frame to a higher layer according to a set output address such that newly received frames are stored in the input addresses having a same pattern with a last pattern of the output addresses in the deinterleaving buffer.

### BRIEF DESCRIPTION OF THE DRAWINGS

The above and other aspects and advantages of the present invention will become more clearly understood from the following detailed description taken in conjunction with the accompanying drawings, in which:

FIG. 1 is a block diagram illustrating an internal structure of a transmitting stage with conventional outer and inner coders;

FIG. 2 illustrates an example of sub-buffers for which Reed-Solomon (RS) coding is performed;

FIG. 3 is a buffer state diagram illustrating a method for managing a deinterleaving buffer in a mobile communication system using block interleaving in accordance with an embodiment of the present invention;

FIG. 4 illustrates an order in which frames stored in a deinterleaving buffer are transferred to a higher layer in accordance with an embodiment of the present invention;

FIG. 5 is a block diagram illustrating an internal structure of an apparatus for managing a deinterleaving buffer in a mobile communication system using block interleaving in accordance with an embodiment of the present invention; and

FIGS. 6A and 6B are flow charts illustrating a method for managing a deinterleaving buffer in a mobile communication system using block interleaving in accordance with an embodiment of the present invention.

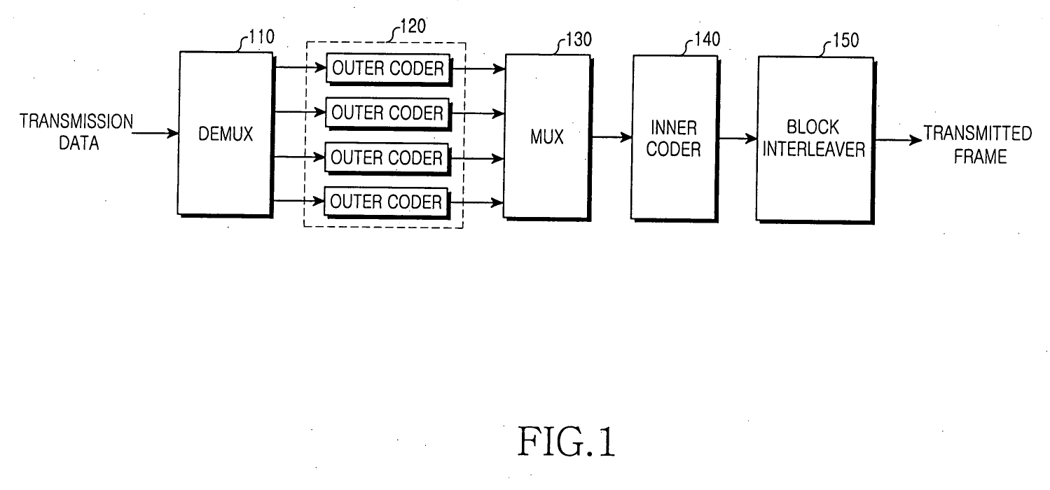

Throughout the drawings, like reference numerals will be understood to refer to like parts, components and structures.

### DETAILED DESCRIPTION OF THE EXEMPLARY EMBODIMENTS

A number of exemplary embodiments of the present invention will be described in detail herein below with reference to the accompanying drawings. In the following description, detailed descriptions of functions and configurations incorporated herein that are well known to those skilled in the art are omitted for clarity and conciseness.

First, a basic concept of an embodiment of the present invention will be described, followed by a detailed description of the exemplary embodiments of the present invention.

According to a method for managing a deinterleaving buffer in accordance with an embodiment of the present invention, inner codes and outer codes serving as Reed-Solomon (RS) codes are configured in the form of product codes, and a decoding operation is implemented using a 64-frame buffer in a receiving stage. After the conventional RS decoding is performed, the buffer of the receiving stage for RS-decoded frames is not collectively emptied, but the frames are transferred to a higher layer one by one in order of sub-buffers.

In embodiments of the present invention, the order in which the RS-decoded frames are transferred to the higher layer is different from a reception order based on the deinterleaving operation. For example, four sub-buffers configuring the buffer of the receiving stage are referred to as Sub-buffers 1 to 4. In a method for receiving frames before decoding, first frame areas of Sub-buffers 1 to 4 are sequentially filled and then second frame areas and other frame areas are sequentially filled.

In a method for transferring the decoded frames to the higher layer, the first to last frames of Sub-buffer 1 are transferred, and then the first to last frames of Sub-buffers 2 to 4 are transferred. That is, embodiments of the present invention perform frame input and output operations in which a frame transfer operation from one buffer to the higher layer is performed in a minimum unit of one frame, and then a frame storing operation for storing a newly received frame in an empty buffer address is performed in a minimum unit of one frame.

Accordingly, embodiments of the present invention do not additionally provide an output buffer for temporarily storing frames before RS-decoded frames are transferred to the higher layer. After RS decoding and deinterleaving are performed in one buffer, the decoded frames can be transferred to the higher layer in the minimum unit of one frame. In embodiments of the present invention, buffer addresses in which received frames are stored are repeated every 64 frames according to a predefined rule.

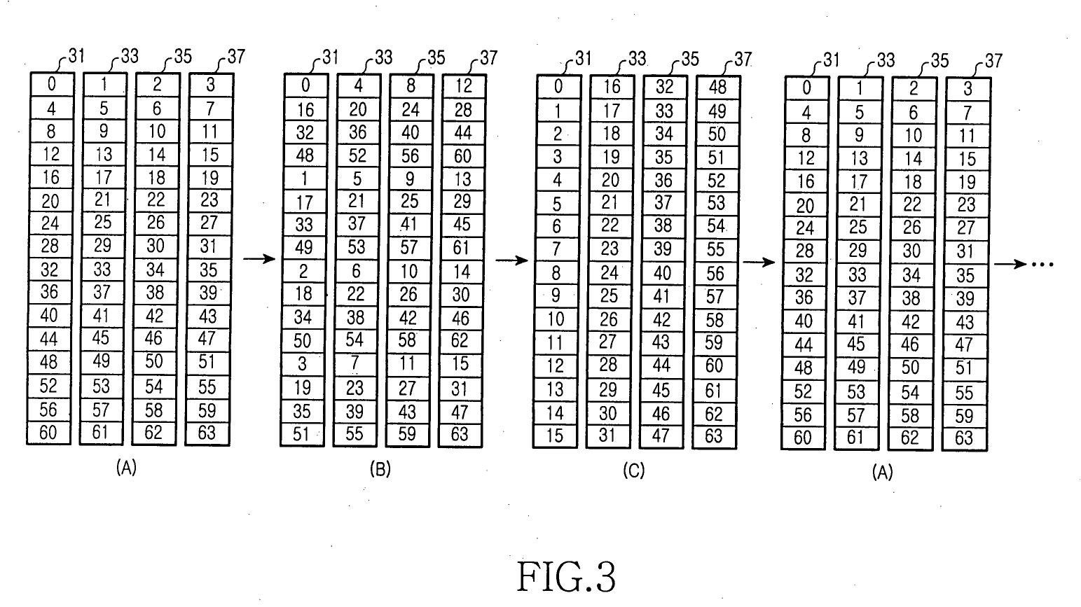

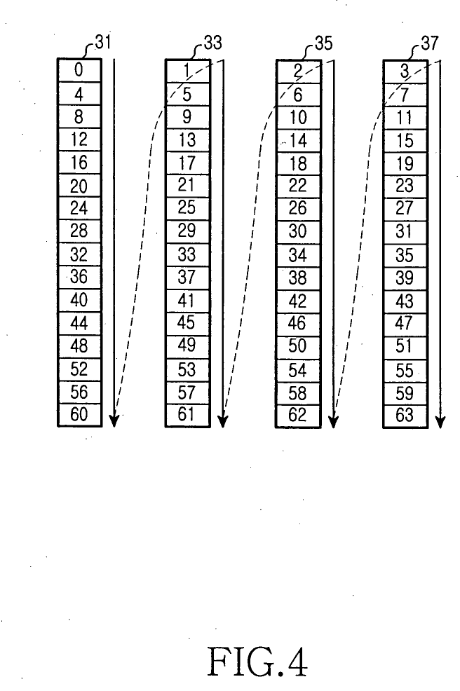

A method in accordance with an embodiment of the present invention will now be described in greater detail with reference to FIGS. 3 and 4.

FIG. 3 illustrates a method for managing a deinterleaving buffer in a mobile communication system using block interleaving in accordance with an embodiment of the present invention. FIG. 3 is a buffer state diagram illustrating buffer addresses to which received frames are input every 64 frames. FIG. 4 illustrates the order in which frames stored in a deinterleaving buffer are transferred to a higher layer in accordance with an embodiment of the present invention.

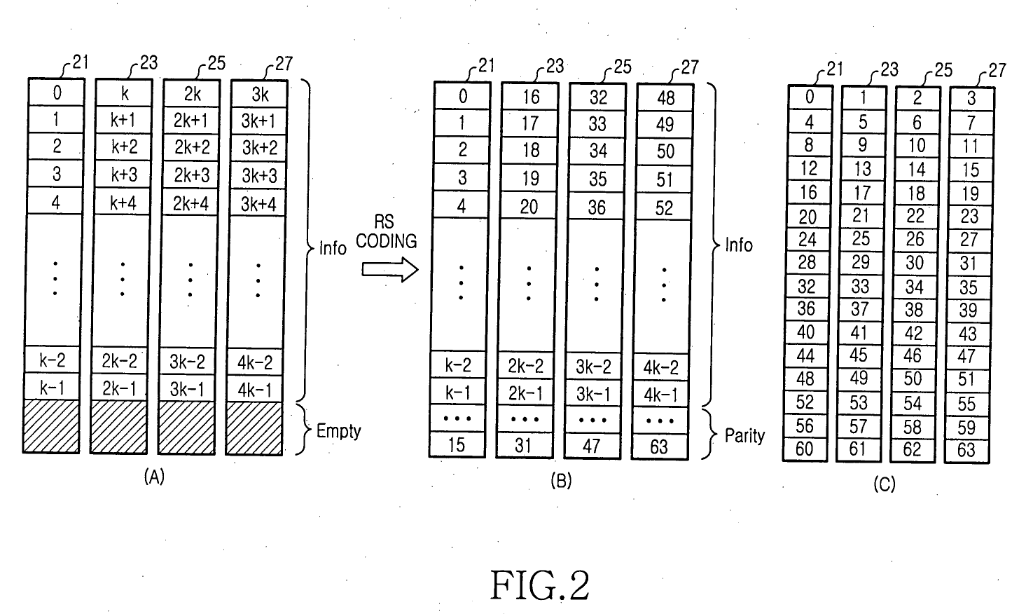

First, when interleaved frames are sent from the transmitting stage as illustrated in part (C) of FIG. 2, the deinterleaving buffer of the receiving stage temporarily stores received frames in buffer addresses that have the patterns of (A)→(B)→(C) of FIG. 3 every 64 frames. The buffer state based on the address pattern as illustrated in part (A) of FIG. 3 is referred to as the first state, and the buffer states based on the address patterns as illustrated in parts (B) and (C) are referred to as the second and third states, respectively. The deinterleaving buffer of FIG. 3 includes, for example, first to fourth sub-buffers 31, 33, 35, and 37.

In the first state, received frames are input in the same pattern as that of the frame transmission order as illustrated in part (C) of FIG. 2. According to the frame input order, first frame areas of the first to fourth sub-buffers 31, 33, 35, and 37 are sequentially filled in a unit of one frame, and second frame areas and other frame areas are filled in the same way as the first frame areas. After frames input in the first state are RS-decoded, they are output to the higher layer in the same order as indicated by the arrows of FIG. 4.

That is, the received frames of part (A) of FIG. 3 are sequentially input to Buffer Addresses 0, 1, 2, 3, . . . , 61, 62, 63, and the RS-decoded frames are output to the higher layer in order of Buffer Addresses 0, 4, 8, . . . , 55, 59, 63 as illustrated in FIG. 4. Because the RS decoding is performed in a sub-buffer unit, it begins at an input time point of a frame selected from Buffer Addresses 60 to 63 in the first buffer state. After frames input to the first sub-buffer 31 in the first buffer state are completely RS-decoded, the decoded frames are output to the higher layer in order of Buffer Addresses 0, 4, 8, . . . on the basis of a reception time point of each frame, and a newly input frame is input to an associated buffer address whenever a frame is output as illustrated in the second state, i.e., part (B) of FIG. 3.

The received frames in the second state, i.e., part (B) of FIG. 3, are sequentially input to Buffer Addresses 0, 4, 8, 12, . . . , 59, 63, and the RS-decoded frames are output to the higher layer in order of Buffer Addresses 0, 16, 32, . . . , 31, 47, 63 in the same way as in the first state. The received frames in the third state, i.e., part (C) of FIG. 3, are sequentially input to Buffer Addresses 0, 16, 32, 48, . . . , 47, 63, and the RS-decoded frames are output to the higher layer in order of Buffer Addresses 0, 1, 2, . . . , 61, 62, 63 in the same way.

According to an exemplary buffer management method in accordance with an embodiment of the present invention, frames input and output to the deinterleaving buffer have a pattern in which the first to third states are regularly cyclic. The RS decoding and deinterleaving operations are performed within one buffer. In this case, after one frame is output to the higher layer, a newly received frame is stored in a buffer address from which the frame has been output. Accordingly, the amount of buffer resources required for the receiving stage is reduced. Because a data copy operation to the conventional output buffer is omitted, frame reception efficiency is improved.

Frame input and output relation Equations for the deinterleaving buffer in which the first to third states are regularly repeated are described in greater detail below with reference to Equations (1) to (6). Parameters and operators used in the following Equations are defined as shown in Table 1. In Equations (1) to (6), [0], [1], and [2] denote the first state, the second state, and the third state of the deinterleaving buffer as illustrated in FIG. 3, respectively, and [i] and [j] denote a frame input state and a frame output state, respectively.

TABLE 1

| Parameter/Operator | Description |
|---|---|
| i | Frame input index |
| j | Frame output index |
| InBufferAddress | Deinterleaving buffer input address |
| OutBufferAddress | Deinterleaving buffer output address |
| A mod B | Remainder of A/B |
| └A/B┘ | Integer less than or equal to A/B |

Equations (1) and (2) are input and output relation equations for the deinterleaving buffer in the first state as illustrated in part (A) of FIG. 3.
InBufferAddress[0][i]=i Equation (1)
OutBufferAddress[0][j]=4×(j mod 16)+└j/16┘ Equation (2)

Equations (3) and (4) are input and output relation equations for the deinterleaving buffer in the second state as illustrated in part (B) of FIG. 3.
InBufferAddress[1][i]=4×(i mod 16)+└i/16┘ Equation (3)
OutBufferAddress[1][j]=16×(j mod 4)+└j/4┘ Equation (4)

When values 0, 1, 2, 3, . . . are sequentially inserted into Output Index j of Equation (2), output addresses of the deinterleaving buffer are set to Output Addresses 0, 4, 8, 12, . . . in the first state. When values 0, 1, 2, 3, . . . are sequentially inserted into Input Index i of Equation (3), input addresses of the deinterleaving buffer are set to Input Addresses 0, 4, 8, 12, . . . in the second state. From the above description, it can be found that the input addresses of the deinterleaving buffer in the second state are set to be the same as the output addresses of the deinterleaving buffer in the first state.

Equations (5) and (6) are input and output relation equations for the deinterleaving buffer in the third state as illustrated in part (C) of FIG. 3.
InBufferAddress[2][i]=16×(i mod 4)+└i/4┘ Equation (5)
OutBufferAddress[2][j]=j Equation (6)

From Equations (4) and (5), it can be found that the input addresses of the deinterleaving buffer in the third state are set to be the same as the output addresses of the deinterleaving buffer in the second state. Similarly, from Equations (6) and (1), it can be found that the input addresses of the deinterleaving buffer in the first state are set to be the same as the output addresses of the deinterleaving buffer in the third state.

That is, when frames are output and input, Equations (2) and (3), Equations (4) and (5), and Equations (6) and (1) can be used to determine the same input and output addresses of the deinterleaving buffer. When the RS decoding is performed, Equations (2), (4), and (6) for setting the output addresses of the deinterleaving buffer are also applied in an order of frames to be input to the outer decoder.

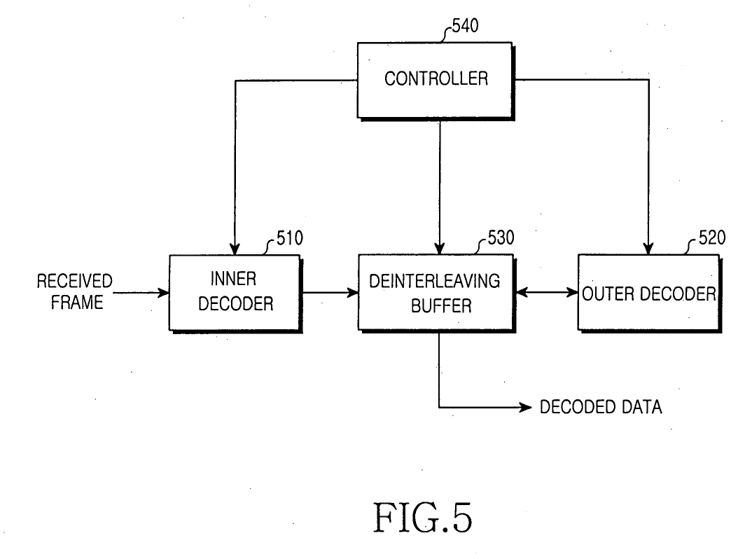

FIG. 5 is a block diagram illustrating an internal structure of an apparatus for managing a deinterleaving buffer in a mobile communication system using block interleaving in accordance with an embodiment of the present invention. The apparatus of FIG. 5 comprises an outer decoder 520 for performing RS decoding, a single deinterleaving buffer 530 for the RS decoding and deinterleaving, and a controller 540 for controlling the outer decoder 520 and the deinterleaving buffer 530 on the basis of a deinterleaving buffer management method according to an embodiment of the present invention. It is assumed in this example that the deinterleaving buffer 530 includes the first to fourth sub-buffers 31, 33, 35, and 37 as illustrated in FIG. 3.

After frames received through a wireless network are channel-decoded through an inner decoder 510 in the apparatus of FIG. 5, the channel-decoded frames are input to the deinterleaving buffer 530 in the first state as illustrated in part (A) of FIG. 3. When the deinterleaving buffer 530 is initially empty, the controller 540 counts the number of frames input to the deinterleaving buffer 530 and sequentially inputs to the first sub-buffer 31, frames received up to a time point when RS decoding for at least one sub-buffer is enabled.

The time point when the RS decoding is enabled is preset to a time point ranging from a time point of receiving a frame of Buffer Address 60, i.e., a 61^{st} received frame, to a time point of receiving a frame of Buffer Address 63, i.e., a 64^{th} received frame, in the first state as illustrated in part (A) of FIG. 3. This preset time point determines a sequence number of an input frame when the 1^{st} frame (i.e., Frame 0) RS-decoded is output to the higher layer in an associated state. It is preferred that a start time point of the RS decoding is set to be close to a reception time point of the 61^{st} frame, such that a margin is set in an output delay time of the deinterleaving buffer 530.

The controller 540 controls the outer decoder 520 and the deinterleaving buffer 530, performs the RS decoding on a sub-buffer-by-sub-buffer basis after the start time point of the RS decoding, and outputs RS-decoded frames to the higher layer in a minimum unit of one frame. In this case, an output order of frames from each sub-buffer is set as illustrated in FIG. 4. The controller 540 performs the RS decoding on frames input in the first state using Equation (1), and outputs the frames to the higher layer using Equation (2). The controller 540 sets an input address of a newly received frame using Equation (3), and stores the frame as in the second state.

Similarly, the controller 540 controls the deinterleaving buffer 530, performs the RS decoding on frames input in the second state, and outputs the frames to the higher layer using Equation (4). The controller 540 sets an input address of a newly received frame using Equation (5), and stores the frame as in the third state. Moreover, the controller 540 performs the RS decoding on frames input in the third state, and outputs the frames to the higher layer using Equation (6). The controller 540 sets an input address of a newly received frame using Equation (1), and stores the frame as in the first state. Consequently, the first and third states are repeated in the deinterleaving buffer 530 when the frame input and output operations are performed.

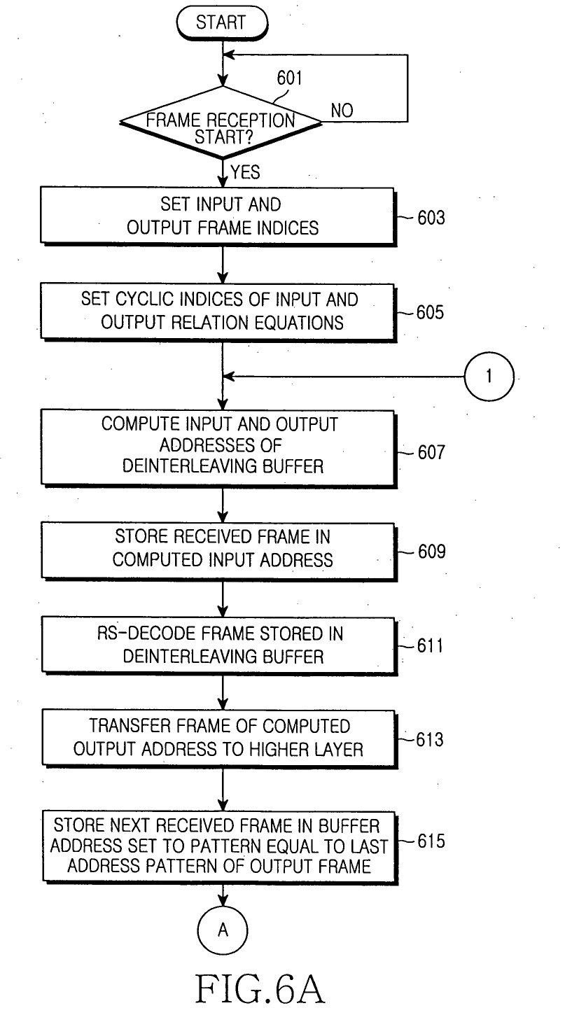

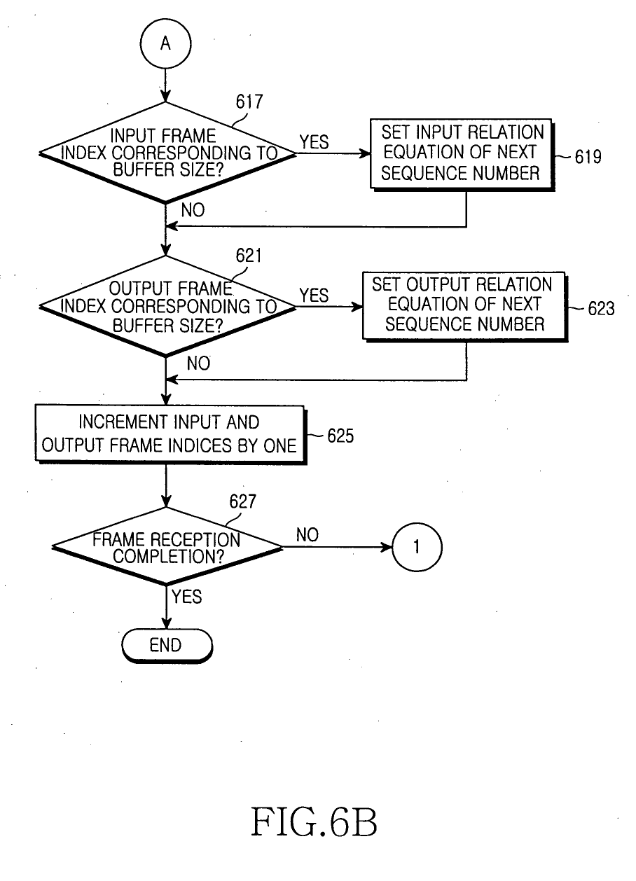

FIGS. 6A and 6B are flow charts illustrating a method for managing a deinterleaving buffer in a mobile communication system using block interleaving in accordance with an embodiment of the present invention. An exemplary method in accordance with an embodiment of the present invention will now be described in greater detail with reference to FIGS. 6A and 6B. A detailed description of content not associated with the embodiment of the present invention, such as an inner decoding process, is omitted from the description of FIGS. 6A and 6B for clarity and conciseness.

First, when the controller 540 of the buffer management apparatus of an embodiment of the preset invention receives frames through the wireless network in step 601, it identifies a transmission sequence number or index of the currently received frame on the basis of information broadcast from a base station (not illustrated), and sets indices of frames to be input and output through the deinterleaving buffer 530 in step 603. In this case, the output frame index is suitably selected on the basis of an output delay time after RS decoding.

The controller 540 sets cyclic indices of the deinterleaving buffer 530 according to Equations (1) to (6) in step 605, and computes input and output addresses of the deinterleaving buffer 530 according to the set cyclic indices in step 607. In this case, the cyclic indices to be applied to Equations (1) to (6) determine the first to third states of the deinterleaving buffer 530 as illustrated in FIG. 3.

The controller 540 stores a received frame in the computed input address of the deinterleaving buffer 530 in step 609. When the empty deinterleaving buffer 530 is filled with received frames at the initial driving time, a received frame input operation is performed, preferably only until a predefined RS decoding time point. When the predefined RS decoding time point is reached, the controller 540 performs the RS decoding on a sub-buffer-by-sub-buffer basis in step 611.

In step 613, the controller 540 outputs the frame stored in the deinterleaving buffer 530 to the higher layer according to the output address of the deinterleaving buffer 530 computed in step 607. In step 615, the controller 540 inputs the next received frame to the same buffer address as an address of the most recent output frame. In this case, frame input and output operations and a state transition process of the deinterleaving buffer 530 have a pattern in which the first to third states are cyclically repeated as described above in relation to FIGS. 3 to 5. When the 1^{st} frame (i.e., Frame 0) RS-decoded is output to the higher layer, a sequence number of an input frame in each state of the deinterleaving buffer 530 is preset to a sequence number of the 61^{st} to 64^{th} frames in an associated state.

After the input and output operations for one frame, the controller 540 determines if an index of the current input frame corresponds to a size of the deinterleaving buffer 530 in step 617. If the index of the current input frame corresponds to the size of the deinterleaving buffer 530, an input relation equation of the next sequence number is set in step 619. Moreover, the controller 540 determines if an index of the current output frame corresponds to the size of the deinterleaving buffer 530 in step 621. If the index of the current output frame corresponds to the size of the deinterleaving buffer 530, an output relation equation of the next sequence number is set in step 623.

In step 625, the controller 540 increments input and output frame indices by one to input and output a frame of the next sequence number. Steps 607 to 627 are then repeated until the frame reception operation is completed. When a buffer address starts from 0, input and output frame indices are counted up to a maximum of 63. When the input and output frame indices exceed 63, they are again counted from 0.

As is apparent from the above description, embodiments of the present invention manage a deinterleaving buffer such that newly received frames are stored in input addresses having a same pattern with a last pattern of output addresses in the deinterleaving buffer after a Reed-Solomon (RS)-decoded frame is output from the deinterleaving buffer of a receiving stage to a higher layer when a transmitting stage uses block interleaving, thereby reducing the number of buffers and buffer capacity required for the receiving stage.

Although a number of exemplary embodiments of the present invention have been disclosed for illustrative purposes, those skilled in the art will appreciate that various modifications, additions, and substitutions are possible without departing from the scope of the present invention. Therefore, the present invention is not limited to the above-described embodiments, but is defined by the following claims, along with their full scope of equivalents.

What is claimed is:

1. A method for managing a deinterleaving buffer configured as a plurality of sub-buffers in a receiving stage of a mobile communication system for performing Reed-Solomon (RS) decoding on frames received through a wireless network, comprising the steps of:
setting cyclic patterns for input and output addresses of the deinterleaving buffer;
performing the RS decoding in a sub-buffer unit after storing received frames in preset input addresses;
outputting RS-decoded frames to a higher layer at a preset time point; and
storing newly received frames in the input addresses having a same pattern with a last pattern of the output addresses in the deinterleaving buffer.

2. The method of claim 1, further comprising the step of:
changing an input relation equation for setting an input address of the deinterleaving buffer whenever an input frame index corresponds to a size of the deinterleaving buffer such that input address patterns of the deinterleaving buffer are regularly cyclic.

3. The method of claim 1, further comprising the step of:
changing an output relation equation for setting an output address of the deinterleaving buffer whenever an output frame index corresponds to a size of the deinterleaving buffer such that output address patterns of the deinterleaving buffer are regularly cyclic.

4. The method of claim 1, wherein the number of the sub-buffers is 4, and wherein the deinterleaving buffer stores 16 frames per sub-buffer and stores a maximum of 64 frames.

5. The method of claim 4, wherein the deinterleaving buffer has input and output address patterns classified according to first, second, and third states, wherein each of the first, second, and third states transition to a next state every 64 frames.

6. The method of claim 5, further comprising the step of:
setting input and output addresses of the deinterleaving buffer in the first state according to the following Equations (1) and (2), respectively:
InBufferAddress[0][i]=i (1)
OutBufferAddress[0][j]=b 4×(j mod 16)+└j/16┘ (2)
wherein, i denotes a frame input index, j denotes a frame output index, InBufferAddress denotes a deinterleaving buffer input address, OutBufferAddress denotes a deinterleaving buffer output address, A mod B denotes a remainder of A/B, and └A/B┘ denotes an integer less than or equal to A/B.

7. The method of claim 6, further comprising the step of:
setting input and output addresses of the deinterleaving buffer in the second state according to the following Equations (3) and (4), respectively:
InBufferAddress[1][i]=4×(i mod 16)+└i/16┘ (3)
OutBufferAddress[1][j]=16×(j mod 4)+└j/4┘ (4)

8. The method of claim 7, further comprising the step of:
setting input and output addresses of the deinterleaving buffer in the third state according to the following Equations (5) and (6), respectively:
InBufferAddress[2][i]=16×(i mod 4)+└i/4┘ (5)
OutBufferAddress[2][j]=j (6)

9. The method of claim 5, further comprising the step of:
setting a time point when a 1^{st} frame RS-decoded is output to the higher layer, in a state of the first to third states, to a time point when a frame of a preset sequence number among 61^{st} to 64^{th} frames is input to the deinterleaving buffer in the state.

10. An apparatus for managing a buffer configured as a plurality of sub-buffers in a receiving stage of a mobile communication system for performing Reed-Solomon (RS) decoding on frames received through a wireless network, the apparatus comprising:
an outer decoder for performing the RS decoding on frames input to a deinterleaving buffer;
the deinterleaving buffer having the plurality of sub-buffers for inputting and outputting the frames received according to preset input and output addresses; and
a controller for setting input and output indices of the received frames and cyclic input and output addresses of the deinterleaving buffer, and controlling the outer decoder and the deinterleaving buffer to output an RS-decoded frame to a higher layer according to a set output address, such that newly received frames are stored in the input addresses having a same pattern with a last pattern of the output addresses in the deinterleaving buffer.

11. The apparatus of claim 10, wherein the controller is configured to initialize an input index and change a predetermined input relation equation for setting an input address of the deinterleaving buffer whenever an input frame index corresponds to a size of the deinterleaving buffer, such that input address patterns of the deinterleaving buffer are regularly cyclic.

12. The apparatus of claim 10, wherein the controller is configured to initialize an output index and change a predetermined output relation equation for setting an output address of the deinterleaving buffer whenever an output frame index corresponds to a size of the deinterleaving buffer, such that output address patterns of the deinterleaving buffer are regularly cyclic.

13. The apparatus of claim 10, wherein the number of the sub-buffers is 4, and wherein the deinterleaving buffer stores 16 frames per sub-buffer and stores a maximum of 64 frames.

14. The apparatus of claim 13, wherein the deinterleaving buffer has input and output address patterns classified according to first, second, and third states, wherein each of the first, second and third states transition to a next state every 64 frames.

15. The apparatus of claim 14, wherein the controller is configured to set input and output addresses of the deinterleaving buffer in the first state according to the following Equations (1) and (2):
InBufferAddress[0][i]=i (1)
OutBufferAddress[0][j]=4×(j mod 16)+└j/16┘ (2)
wherein, i denotes a frame input index, j denotes a frame output index, InBufferAddress denotes a deinterleaving buffer input address, OutBufferAddress denotes a deinterleaving buffer output address, A mod B denotes a remainder of A/B, and └A/B┘ denotes an integer less than or equal to A/B.

16. The apparatus of claim 15, wherein the controller is configured to set input and output addresses of the deinterleaving buffer in the second state according to the following Equations (3) and (4):
InBufferAddress[1][i]=4×(i mod 16)+└i/16┘ (3)
OutBufferAddress[1][j]=16×(j mod 4)+└j/4┘ (4)

17. The apparatus of claim 16, wherein the controller is configured to set input and output addresses of the deinterleaving buffer in the third state according to the following Equations (5) and (6):
InBufferAddress[2][i]=16×(i mod 4)+└i/4┘ (5)
OutBufferAddress[2][j]=j (6)

18. The apparatus of claim 14, wherein the controller is configured to set a time point when a 1^{st} frame RS-decoded is output to the higher layer, in a state of the first to third states, to a time point when a frame of a preset sequence number among 61^{st} to 64^{th} frames is input to the deinterleaving buffer in the state.

19. The apparatus of claim 17, wherein the Equations (2), (4), and (6) are applied in an order of frames to be input to the outer decoder when the RS decoding is performed.
